(19) United States
(12) Patent Application Publication
(10) Pub. No.: US 2026/0058648 A1
(43) Pub. Date: Feb. 26, 2026

(54) GATE DRIVER

(71) Applicant: HYUNDAI MOBIS CO., LTD., Seoul (KR)

(72) Inventors: Won Hee JO, Seoul (KR); Hyung Min PARK, Seoul (KR); Kwan YOON, Seoul (KR); Min Jae YOO, Seoul (KR); Yeon Ho KIM, Seoul (KR)

(73) Assignee: HYUNDAI MOBIS CO., LTD., Seoul (KR)

(21) Appl. No.: 19/215,277

(22) Filed: May 21, 2025

(30) Foreign Application Priority Data
Aug. 21, 2024 (KR) 10-2024-0112262

(51) Int. Cl. H03K 17/16

(52) U.S. Cl. CPC H03K 17/161; H03K 17/168; H03K 2217/0063; H03K 2217/0072

(57) ABSTRACT

A gate driver includes an output line coupled with a gate of a transistor, a high-side inverter including a first switch and a second switch each coupled at a first end with the output line and coupled at a second end with a first voltage source, a low-side inverter including a third switch and a fourth switch each coupled at a first end with the output line and coupled at a second end with a second voltage source, a sensor unit including a current sensor coupled with the transistor to sense a collector-emitter current of the transistor, and a control circuit coupled with the sensor unit and the first to fourth switches to turn on or turn off the transistor.

### CROSS REFERENCE TO RELATED APPLICATION

The present application claims priority to Korean Patent Applications No. 10-2024-0112262, filed on Aug. 21, 2024, the entire contents of which are incorporated herein for all purposes by this reference.

### BACKGROUND

### Technical Field

The present disclosure relates to a gate driver of a transistor and, in more detail, to a gate driver that can reduce overshoot in a fast switching process of a transistor.

### Description of the Related Art

A gate driver refers to a circuit that controls the on/off switching operation of a transistor by adjusting driving voltage and current that are applied to the gate of transistors such as an Insulated Gate Bipolar mode Transistor (IGBT) and a Metal Oxide Semiconductor Field Effect transistor (MOSFET).

When a gate driver is designed to have a high driving voltage slew rate during on/off operations, a transistor can achieve faster switching, whereby it is possible to reduce power loss during the switching process of the transistor.

However, a rapid change in driving voltage causes overshoot and ringing in a gate voltage and induces electromagnetic interference (EMI), whereby it may affect stable operation of a transistor and surrounding circuits.

The description provided above as a related art of the present disclosure is just for helping understanding the background of the present disclosure and should not be construed as being included in the related art known by those skilled in the art.

### SUMMARY

An objective of the present disclosure is to provide a gate driver that can minimize overshot while providing fast on/off switching in consideration of the switching performance that depends on the temperature of a transistor.

Another objective of the present disclosure is to provide a gate driver that minimizes a loss of power during a switching process and improves reliability.

The technical subjects to implement in the present disclosure are not limited to the technical problems described above and other technical subjects that are not stated herein will be clearly understood by those skilled in the art from the following specifications.

In order to achieve the objectives, a gate driver according to an embodiment of the present disclosure includes: an output line coupled with a gate of a transistor; a high-side inverter comprising a first switch and a second switch each coupled at a first end with the output line and coupled at a second end with a first voltage source; a low-side inverter comprising a third switch and a fourth switch each coupled at a first end with the output line and coupled at a second end with a second voltage source; a sensor unit comprising a current sensor coupled with the transistor and configured to sense a collector-emitter current of the transistor; and a control circuit coupled with the sensor unit and the first, second, third, and fourth switches and configured to turn on or turn off the transistor, wherein when a turn-on signal is input, the control circuit turns on the first switch and selectively turns on the second switch based on a result of comparing the collector-emitter current and a preset target current.

According to one embodiment, the control circuit may include a current source configured to output the preset target current and a comparator coupled with the current source and the sensor unit and configured to output a signal when the sensed current is higher than a current output from the current source; the first switch may be turned on in accordance with the turn-on signal; and the second switch may be selectively turned on in accordance with the turn-on signal and output from the comparator.

According to an embodiment, the control circuit may include a signal processing circuit coupled with the comparator and the second switch and configured to turn on the second switch when the turn-on signal is input and a signal is not output from the comparator.

According to an embodiment, the control circuit may turn off both of the third switch and the fourth switch of the low-side inverter when the turn-on signal is input.

According to an embodiment, the sensor unit may further include a voltage sensor configured to sense a collector-emitter voltage of the transistor, and when a turn-off signal is input, the control circuit may turn on the third switch and selectively turn on the fourth switch based on a result of comparing the collector-emitter voltage and a preset target voltage.

According to one embodiment, the control circuit may include a voltage source configured to output the preset target voltage and a comparator coupled with the voltage source and the sensor unit and configured to output an on-signal when the sensed voltage is higher than or the same as a voltage output from the voltage source; the third switch may be turned on in accordance with the turn-off signal; and the fourth switch may be selectively turned on in accordance with the turn-off signal and output from the comparator.

According to an embodiment, the control circuit may include a signal processing circuit coupled with the comparator and the fourth switch and configured to turn on the fourth switch when the turn-on signal is input and a signal is not output from the comparator.

According to an embodiment, the control circuit may turn off both of the first switch and the second switch of the low-side inverter when the turn-off signal is input.

According to an embodiment, the first switch and the second switch each may be a PMOS, sources of the first switch and the second switch may be connected with the first voltage source, and drains of the first switch and the second switch may be connected with the output line; and the third switch and the fourth switch each may be an NMOS, sources of the first switch and the second switch may be connected with the second voltage source, and drains of the first switch and the second switch may be connected with the output line.

According to an embodiment, the current sensor may include a hall sensor coupled at a first end with an emitter of the transistor and coupled at a second end with the control circuit.

According to an embodiment, the voltage sensor may further include a voltage scaler coupled at a first end with a collector of the transistor, coupled at a second end with the control circuit, and configured to decrease a collector voltage of the transistor.

According to an embodiment, the gate driver may further include: a diode coupled at a first end with the control circuit, coupled at a second end with the voltage sensor, and configured such that a current flows only toward the voltage sensor; and a current source coupled at an end with the diode and the control circuit to prevent floating due to the diode.

According to an embodiment, there can be provided a gate driver that can minimize overshot while providing fast on/off switching operations in consideration of the switching performance that depends on the temperature of a transistor.

Further, a gate driver that minimizes a loss of power during a switching operation of a transistor and improves reliability can be provided.

The effects that can be obtained by the present disclosure are not limited to the effects described above and other effects can be clearly understood by those skilled in the art from the following description.

### BRIEF DESCRIPTION OF THE DRAWINGS

FIG. 1 is a diagram illustrating the structure of a gate driver according to an embodiment of the present disclosure;

FIG. 2 shows a turn-on operation of a power transistor based on a driving voltage slew rate of a gate driver;

FIG. 3 and FIG. 4 are diagrams showing voltage and current graphs of a transistor in on/off switching processes.

FIG. 5 is a diagram illustrating the structure of a 2-level gate driver according to an embodiment of the present disclosure;

FIG. 6 is a circuit diagram showing a gate driver according to an embodiment of the present disclosure;

FIG. 7 is a circuit diagram showing, in detail, a current-voltage sensor unit of a gate driver according to an embodiment of the present disclosure;

FIG. 8 is a circuit diagram showing a gate driver equipped with a surge voltage prevention circuit according to an embodiment of the present disclosure;

FIG. 9 is a graph illustrating turn-on and turn-off switching operations of a 2-level gate driver according to an embodiment of the present disclosure;

FIG. 10 is a graph showing a gate voltage corresponding to a drain-source current of a transistor according to an embodiment of the present disclosure; and

FIG. 11 is a graph showing a gate voltage corresponding to a drain-source voltage of a transistor according to an embodiment of the present disclosure.

### DETAILED DESCRIPTION

Hereafter, embodiments of the present disclosure will be described in detail with reference to the accompanying drawings and the same or similar components are given the same reference numerals regardless of the numbers of figures and are not repeatedly described.

Terms “module” and “unit” that are used for components in the following description are used only for the convenience of description without having discriminate meanings or functions.

In the following description, if it is decided that the detailed description of known technologies related to the present disclosure makes the subject matter of the embodiments described herein unclear, the detailed description is omitted.

Further, the accompanying drawings are provided only for easy understanding of embodiments disclosed in the specification, the technical spirit disclosed in the specification is not limited by the accompanying drawings, and all changes, equivalents, and replacements should be understood as being included in the spirit and scope of the present disclosure.

Terms including ordinal numbers such as “first” and “second” may be used to describe various components, but the components are not to be construed as being limited to the terms. The terms are used only to distinguish one component from another component.

It is to be understood that when one element is referred to as being “connected to” or “coupled to” another element, it may be connected directly to or coupled directly to another element or be connected to or coupled to another element with the other element therebetween. On the other hand, it should be understood that when one element is referred to as being “connected directly to” or “coupled directly to” another element, it may be connected to or coupled to another element without the other element therebetween.

Singular forms are intended to include plural forms unless the context clearly indicates otherwise.

It will be further understood that the terms “comprise” or “have” used in this specification specify the presence of stated features, steps, operations, components, parts, or a combination thereof, but do not preclude the presence or addition of one or more other features, numerals, steps, operations, components, parts, or a combination thereof.

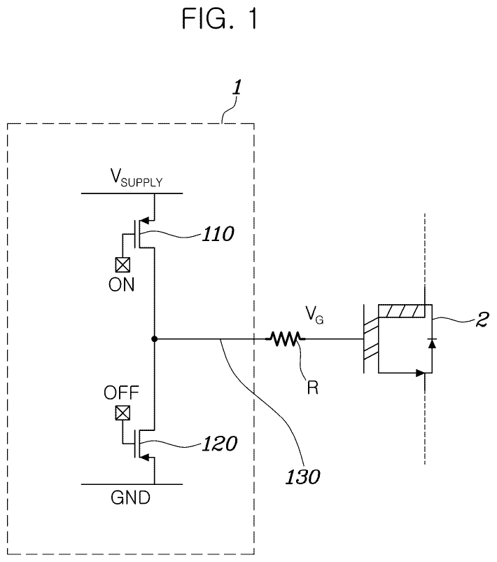

FIG. 1 is a diagram illustrating the structure of a gate driver according to an embodiment of the present disclosure.

Referring to FIG. 1, a gate driver 1 includes a high-side inverter 110, a low-side inverter 120, an output line 130 connected to a power transistor 2, and an output resistor R.

The gate driver 1 may mean a circuit that provides voltage and current for fast and efficiency on/off switching operations of the power transistor 2.

The power transistor 2 may mean a device that performs a switching operation based on a gate voltage. For example, in a high-voltage and high-current circuit, the power transistor 2 may be a power device such as a MOSFET and an IGBT.

The high-side inverter 110 may include at least one or more switches 111. As the switch 111 of the high-side inverter 110, a device that can be controlled to turn on/off based on electrical signals of a BJT, an IGBT, and a MOSFET, etc. For example, the high-side inverter 110 may be a single PMOS and can be controlled to turn on/off based on a PWM signal that is applied for a gate voltage of the PMOS.

The source terminal of the high-side inverter 110 is coupled with a first voltage source V_supply and the drain terminal thereof is coupled with the output line 130, whereby the high-side inverter 110 can be turned on/off based on a turn-on signal that is input to the gate terminal.

The low-side inverter 120 may include at least one or more switches. As the switch of the low-side inverter 120, a device that can be controlled to turn on/off based on electrical signals of a BJT, an IGBT, and a MOSFET, etc. For example, the low-side inverter 120 may be a single PMOS and can be controlled to turn on/off based on a PWM signal that is applied for a gate voltage of the PMOS.

The source terminal of the low-side inverter 120 is coupled with a second voltage source V_GND and the drain terminal thereof is coupled with the output line 130, whereby the low-side inverter 120 can be turned on/off based on a turn-off signal that is input to the gate terminal.

The output line 130 and the power transistor 2 are connected, whereby it is possible to turn on or turn off the power transistor 2 by adjusting the gate voltage of the power transistor through switching operations of the high-side inverter 110 and the low-side inverter 120.

In detail, when all of the switches of the high-side inverter 110 are turned on and all of the switches of the low-side inverter 120 are turned off, it is possible to turn on the power transistor 2 by increasing the gate voltage.

When all of the switches of the low-side inverter 120 are turned on and all of the switches of the high-side inverter 120 are turned off, it is possible to turn off the power transistor 2 by decreasing the gate voltage.

The resistor R is connected to the output line 130, so overshoot due to rapid variation of the gate voltage of the power transistor 2 can be prevented. However, the resistor R of the output line 130 may increase the on/off driving time during on/off operations of the power transistor 2, whereby it may cause a high power loss of the gate driver 1 and increase the temperature of surrounding power devices.

The power transistor 2 may mean a power device that can perform on/off switching operations based on the voltage at the gate terminal of a MOSFET, IGBT, etc. For example, the power transistor 2 may be an IGBT that can operate at a driving voltage over 600V. In this case, the power transistor 2 may include a parasitic inductance component therein, and the switching operation of the power transistor 2 may not be performed immediately when a signal is input to the gate terminal of the transistor 2.

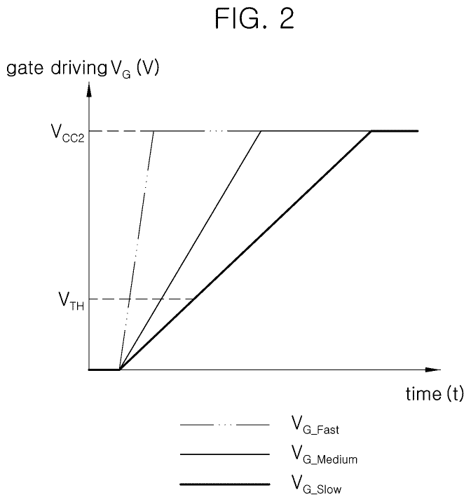

FIG. 2 shows a turn-on operation of the power transistor 2 based on a driving voltage slew rate of the gate driver 1.

Referring to FIG. 2, the turn-on operation of the power transistor 2 of the gate driver with driving voltage slew rates is shown in the order of V_G_fast, V_G_medium, and V_G_slow in a voltage vs. time graph where time is on the horizontal axis and voltage is on the vertical axis.

It can be seen that the gate voltage is not increased up to an on-voltage immediately when a turn-on signal is transmitted to the gate of the transistor 2, so it takes time for a saturation voltage Vcc2, at which the transistor 2 is turned on, to be reached.

Further, it can be seen that the turn-on time of the transistor 2 becomes faster in the order of V_G_fast, V_G_Medium, V_G_SLOW, as the driving voltage slew rate of the gate driver increases.

However, when the driving voltage slew rate increases, overshoot of a drain-source voltage V_DS and a drain-source current I_DS of the transistor 2 may increase during on/off operations.

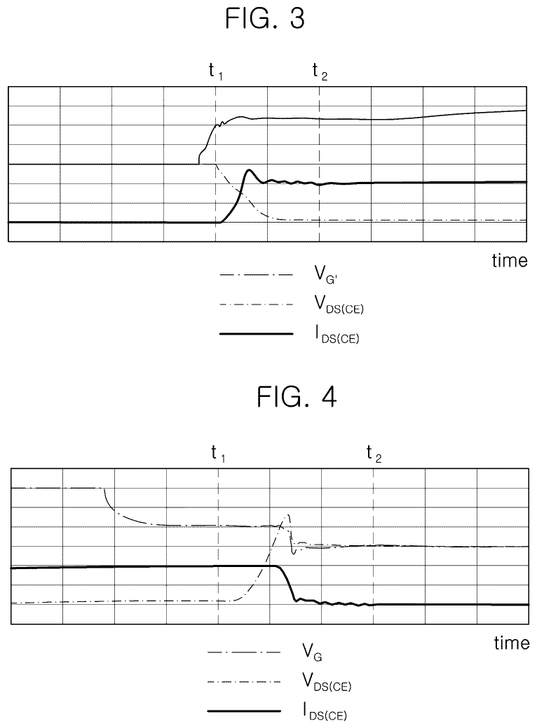

FIG. 3 and FIG. 4 are diagrams showing voltage and current graphs of a transistor in on/off switching processes.

Referring to FIG. 3, a gate voltage V_G, a drain-source voltage V_DS, and a drain-source current I_DS of the transistor 2 in a turn-on process are shown in a graph in which the vertical axis is voltage or current over time that is the horizontal axis.

In this case, it can be seen that when the gate voltage slew rate is large, overshoot is generated in the drain-source current I_DS of the power transistor 2 in the turn-on operation of the power transistor 2.

Referring to FIG. 4, a gate voltage V_G, a drain-source voltage V_DS, and a drain-source current I_DS of the transistor 2 in a turn-off process are shown in a graph in which the vertical axis is voltage or current over time that is the horizontal axis.

In this case, it can be seen that when the gate voltage slew rate is large, overshoot is generated in the drain-source voltage V_DS of the power transistor 2 in the turn-off operation of the power transistor 2.

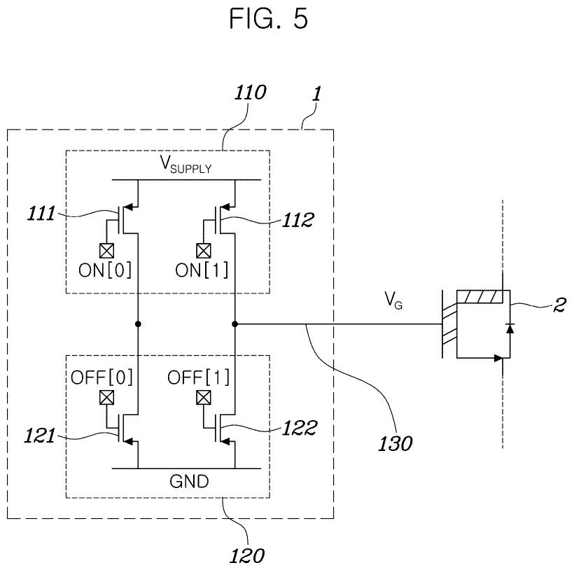

FIG. 5 is a diagram illustrating inverters of a 2-level gate driver according to an embodiment of the present disclosure.

Referring to FIG. 5, the gate driver 1 may include: a high-side inverter 110 including a first switch 111, a second switch 112, and a first voltage source V_supply; a low-side inverter 120 including a third switch 121, a fourth switch 122, and a second power source V_GND; and an output line 130.

Hereafter, a signal that is applied to the gate of the first switch 111 is defined as a first signal ON[0], a signal that is applied to the gate of the second switch 112 is defined as a second signal ON[1], a signal that is applied to the gate of the third switch 121 is defined as a third signal OFF[0], and a signal that is applied to the gate of the fourth switch 122 is defined as a fourth signal OFF[1].

The high-side inverter 110 may include a plurality of switches that can be controlled to turn on/off based on a PWM signal that is applied to the gate terminal of each of the switches.

For example, the first switch 111 and the second switch 112 both may be PMOSs and may be configured such that the sources of the first switch 111 and the second switch 112 are connected to the first voltage source V_supply and the drains of the first switch 111 and the second switch 112 are connected to the output line 130.

The first signal ON[0] and the second signal ON[1] may be coupled to the gate of the first switch 111 and the gate of the second switch 112, respectively, whereby on/off of the switches 111 and 112 can be controlled.

For example, when the first signal ON[0] is transmitted to the gate of the first switch 111, the first switch 111 can be turned on, and when the first signal ON[0] is not transmitted, the first switch 111 can be changed into an off state.

Similarly, the low-side inverter 120 may include a plurality of switches of which on/off switching can be controlled based on a PWM signal that is applied to the gate terminal of each of the switches.

For example, the third switch 121 and the fourth switch 122 both may be PMOSs and may be configured such that the sources of the third switch 121 and the fourth switch 122 are connected to the second voltage source V_GND and the drains of the third switch 121 and the fourth switch 122 are connected to the output line 130.

The third signal OFF[0] and the fourth signal OFF[1] may be coupled to the gate of the third switch 121 and the gate of the fourth switch 122, respectively, whereby on/off of the switches 121 and 122 can be controlled.

For example, when the third signal OFF[0] is transmitted to the gate of the third switch 121, the third switch 121 can be turned on, and when the third signal OFF[0] is not transmitted, the third switch 121 can be changed into an off state.

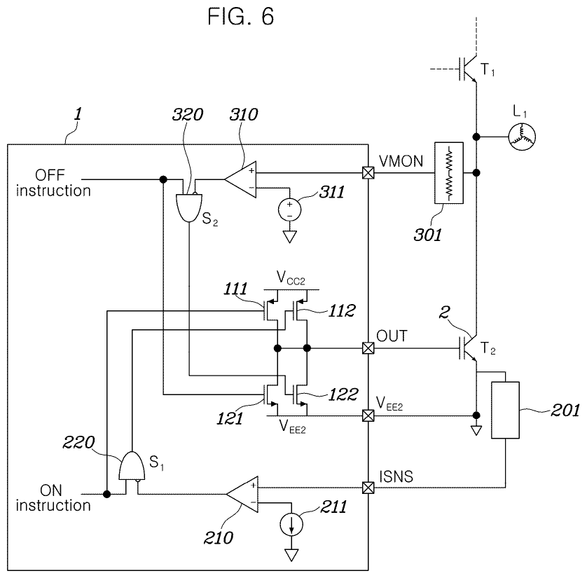

FIG. 6 is a circuit diagram showing a gate driver according to an embodiment of the present disclosure.

Referring to FIG. 6, the gate driver 1 may include a high-side inverter 110, a low-side inverter 120, an output line 130, a voltage scaler 201, a first comparator 210, a third voltage source 211, a first signal processing circuit 220, a current sensor 301, a second comparator 310, a first current source 311, and a second signal processing circuit 320.

The high-side inverter 110 can perform on/off switching operations of the first switch 111 and the second switch 112 based on a turn-on signal and a signal transmitted from the second signal processing circuit 320.

In detail, a turn-on instruction can be coupled with the gate terminal of the first switch 111, thereby being able to selectively turn on the first switch 111. A signal S1 transmitted from the second signal processing circuit 320 can be coupled with the gate terminal of the second switch 112, thereby being able to selectively turn on the second switch 112.

The turn-on signal may be the first signal ON[0] for the first switch 111 and may be the second signal ON[1] for the second switch 112 by being combined with output of the first comparator 210 at the first signal processing circuit 220.

The slew rate of the driving voltage that is output to the second switch 112 is designed to be larger than the slew rate of the driving voltage that is output to the first switch 111, so the gate voltage more quickly increases in the early stage of turn-on driving in which both of the first switch 111 and the second switch 112 are turned on, whereby they can be turned on more quickly. Further, in the later stage of turn-on driving in which only the first switch 111 is turned on and the second switch 112 is turned off, it is possible to suppress generation of overshoot by more slowly increasing the gate voltage.

The low-side inverter 110 can perform on/off switching operations of the third switch 121 and the fourth switch 122 based on a turn-off signal and a signal transmitted from the first signal processing circuit 220.

In detail, a turn-off instruction can be coupled with the third switch 121, thereby being able to selectively turn on the third switch 121. A signal S2 transmitted from the second signal processing circuit 320 can be coupled with the gate of the fourth switch 122, thereby being able to selectively turn on the fourth switch 122.

The turn-off signal may be the third signal OFF[0] for the third switch 121 and may be the fourth signal OFF[1] for the fourth switch 122 by being combined with output of the second comparator 310 at the second signal processing circuit 320.

The reduction amount of the driving voltage that is output to the fourth switch 122 is designed to be larger than the reduction amount of the driving voltage that is output to the third switch 121, so the gate voltage more quickly decreases in the early stage of turn-off driving in which both of the third switch 121 and the fourth switch 122 are turned off, whereby they can be turned off more quickly. Further, in the later stage of turn-off driving in which only the third switch 121 is turned on and the fourth switch 122 is turned off, it is possible to suppress generation of overshoot by more slowly decreasing the gate voltage.

The current sensor 210 can be coupled with the source terminal of the power transistor 2 and can sense the drain-source current I_DS of the power transistor 2.

The first comparator 210 can be coupled with the current sensor 210 and a comparator current source 211 that outputs a preset target current, whereby it can selectively output a signal by comparing the sensed current I_DS and the current that is output to the comparator current source 211.

In detail, when a sensed voltage is larger than a current output from the comparator current source 211, the first comparator 210 can output a signal to the output terminal of the first comparator 210 coupled with the input terminal of the first signal processing circuit 220.

The first signal processing circuit 220 can be coupled with a turn-on instruction input terminal, the first comparator 210, and the second switch 112 and can selectively turn on the second switch 112 based on a transmitted turn-on signal and an output signal of the first comparator 210.

In detail, when a turn-on signal is input to the first signal processing circuit 220 and a signal is not output from the first comparator 210, the first signal processing circuit 220 can turn on the second switch 112 by outputting a signal S1 to the gate of the second switch 112.

The voltage scaler 301 can be coupled with the drain of the power transistor 2 and can sense the drain-source voltage V_ds of the power transistor 2.

The second comparator 310 can be coupled with the voltage scaler 301 and a comparator voltage source 311 that outputs a preset target voltage, whereby it can selectively output a signal by comparing the sensed voltage and the voltage that is output to the comparator voltage source 311.

In detail, when a sensed voltage V_DS is larger than a voltage Vds_Gtarget output from the comparator voltage source 311, the second comparator 310 can output a signal to the output terminal of the second comparator 310 coupled with the input terminal of the second signal processing circuit 320.

In this case, the voltage that is output to the comparator voltage source 311 may be set in consideration of the gate voltage slew rate based on the device temperature of the transistor 2.

The second signal processing circuit 320 can be coupled with a turn-off instruction input terminal, the second comparator 310, and the second switch 122 and can selectively turn on the fourth switch 122 based on a signal transmitted from the second comparator 310 and an input turn-off instruction.

In detail, when a turn-off signal is input to the second signal processing circuit 320 and a signal is not output from the second comparator 320, the second signal processing circuit 320 can turn on the fourth switch 122 by outputting a signal S2 to the gate of the fourth switch 122.

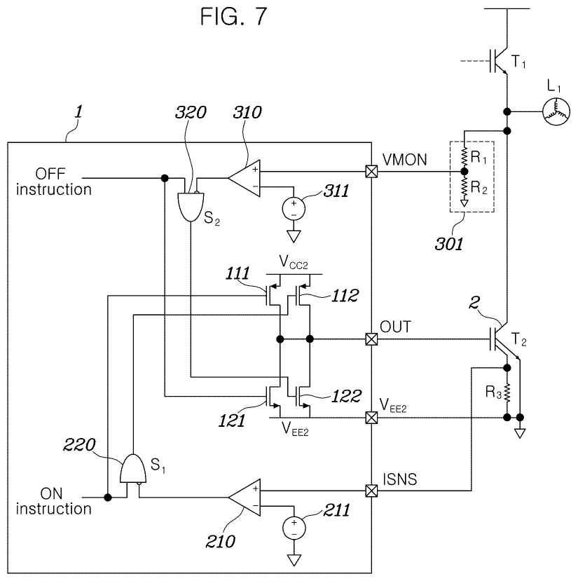

FIG. 7 is a circuit diagram showing, in detail, a current-voltage sensor unit of a gate driver according to an embodiment of the present disclosure.

Referring to FIG. 7, the voltage scaler 201 may include a first resistor R1 and a second resistor R2 and the current sensor 301 may include a shunt resistor R3.

The resistance ratio of the first resistor R1 and the second resistor R2 of the voltage scaler 201 may be set to decrease a voltage that is applied to the gate driver 1 from the power transistor 2.

For example, when the maximum voltage that is applied to a load L1 from a battery V_bat connected to the drain terminal of the power transistor 2 is 800V, the resistance ratio of the first resistor R1 and the second resistor R2 may be set as 1:200 such that a voltage within 4V is applied to the first comparator 301.

The current sensor 301 may include a shunt resistance R3 for measuring a train-source current of the power transistor 2.

For example, a drain-source current flowing in the process of driving the load L1 of the power transistor 2 is 400 A, the shunt resistor R3 may be configured to 5Ω such that the sensing ratio of a current pin is about 1:1000.

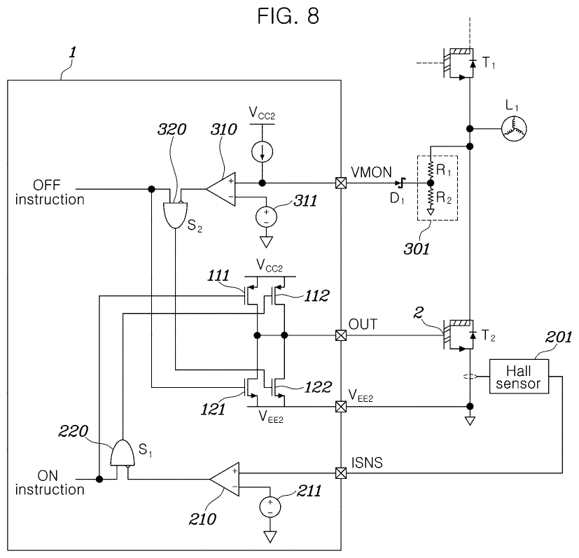

FIG. 8 is a circuit diagram showing a gate driver equipped with a surge voltage prevention circuit according to an embodiment of the present disclosure.

Referring to FIG. 8, the gate driver 1 may include a diode D1 for preventing a surge voltage and a first current source I1.

The diode D1 may be coupled at an end to the first comparator 210 and coupled at another end to the voltage sensor 201 such that a current flows only in the direction from the first comparator 210 to the voltage scaler 201.

However, when the diode D1 is reverse biased, a floating state in which current does not flow to the node connected to the first comparator 210 may be implemented.

An end of the first current source I1 is coupled with the diode D1 and the first comparator 210, whereby it is possible to prevent floating due to the diode D1. In this case, the resistance ratio of the first resistor R1 and the second resistor R2 of the voltage scaler 201 may be designed additionally in consideration of the voltage that is applied due to the first current source I1.

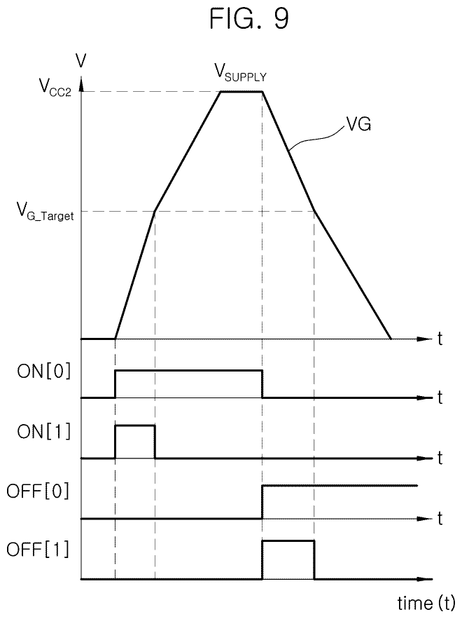

FIG. 9 is a graph illustrating turn-on and turn-off switching operations of a 2-level gate driver according to an embodiment of the present disclosure.

Referring to FIG. 9, a gate driving voltage of the power transistor 2 is shown in the upper graph in which the vertical axis is voltage over time that is the horizontal axis, and the first to fourth signals ON[0], ON[1], OFF[0], and OFF[1] are shown in the lower graphs in which the vertical axis is voltage over time that is the horizontal axis.

In this case, the first signal ON[0] that is transmitted to the first switch 111 may correspond to the turn-on instruction in FIG. 6 to FIG. 8, the second signal ON[1] that is transmitted to the second switch 112 may correspond to a signal S1 that is output from the first signal processing circuit 220 in FIG. 6 and FIG. 8, the third signal OFF[0] that is transmitted to the third switch 121 may correspond to the turn-off instruction in FIG. 6 to FIG. 8, and the fourth signal OFF[1] that is transmitted to the fourth switch 122 may correspond to a signal S2 that is output from the second signal processing circuit 320.

The 2-level gate driver 1 performs turn-on and turn-off switching operations of the power transistor 2 each in two steps, so overshoot can be reduced and relatively fast switching operations can be achieved.

In detail, when a turn-on signal is input to the gate driver 1 and a gate voltage V_G is lower than or the same as a target gate voltage V_Gtarget, the first signal ON[0] and the second signal ON[1] are transmitted to the first switch 111 and the second switch 112, respectively, and the first switch 111 and the second switch 112 both can be turned on. In this case, the gate voltage of the output terminal 130 can relatively rapidly increase.

When a turn-on signal is input to the gate driver 1 and a gate voltage V_G is higher than a target gate voltage V_Gtarget, the first signal ON[0] is transmitted to the first switch 111 but a signal is output from the second comparator 310, so the second signal ON[1] may not be output from the second signal processing circuit 320. In this case, the first switch 111 can be turned on and the second switch 112 can be turned off. In this case, the gate voltage of the output terminal 130 may relatively gradually increase, as compared with when the first switch and the second switch are both turned on.

When a turn-off signal is input to the gate driver 1 and a gate voltage V_G is higher than or the same as a target gate voltage V_Gtarget, the third signal OFF[0] and the fourth signal OFF[1] are transmitted to the third switch 121 and the fourth switch 122, respectively, and the switch 121 and the fourth switch 122 both can be turned on. In this case, the gate voltage of the output terminal 130 can relatively rapidly decrease.

When a turn-off signal is input to the gate driver 1 and a gate voltage V_G is lower than a target gate voltage V_Gtarget, the third signal OFF[0] is transmitted to the third switch 121 but a signal is output from the first comparator 210, so the fourth signal OFF[1] may not be output from the first signal processing circuit 220. In this case, the third switch 121 can be turned on and the fourth switch 122 can be turned off. In this case, the gate voltage of the output terminal 130 may relatively gradually increase, as compared with when the third signal 121 and the fourth signal 122 are both turned on.

When a turn-on signal is input to the gate driver 1, the third switch 121 and the fourth switch 122 of the low-side inverter 120 both can be turned off, and when a turn-off signal is input to the gate driver 1, the first switch 111 and the second switch 112 of the high-side inverter 110 both can be turned off.

The gate voltage V_Gtarget may be changed in accordance with driving temperature, aging, etc. The circuit of the gate driver 1 shown in FIG. 6 to FIG. 8 can perform turn-on and turn-off switching operations of the power transistor 2 based on preset drain-source current I_DS and drain-source voltage V_DS instead of a target gate voltage V_Gtarget.

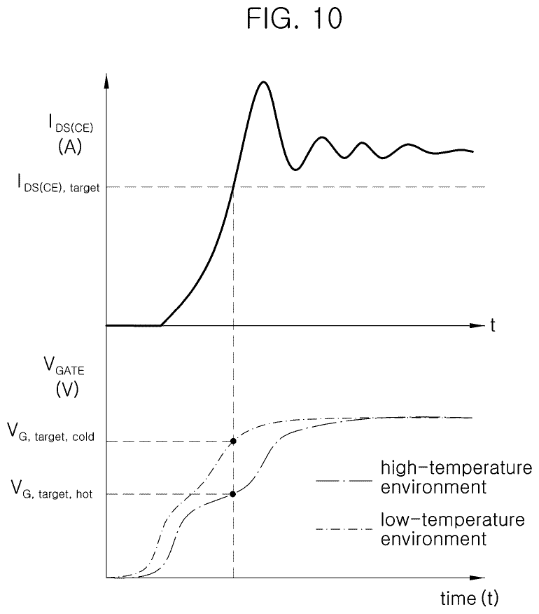

FIG. 10 is a graph showing a gate voltage corresponding to a drain-source current of a transistor in a turn-on process according to an embodiment of the present disclosure.

Referring to FIG. 10, a drain-source current I_DS of the power transistor 2 in a turn-on process is shown in the upper graph in which the vertical axis is current over time that is the horizontal axis, and a gate voltage V_G of the power transistor 2 in a high-temperature environment and a low-temperature environment is shown in the lower graphs in which the vertical axis is current over time that is the horizontal axis.

When the turn-on switching step of the transistor 2 is divided based on the drain-source current I_DS of the transistor, the time point at which the turn-on switching step changes may be changed, depending on a high-temperature environment and a low-temperature environment.

In detail, in a high-temperature environment, the first switch 111 and the second switch 112 both can be turned on until the gate voltage V_G reaches V_Gtarget, hot, and the second switch 112 can be turned off after the gate voltage V_G reaches V_Gtarget, hot.

As compared with using a fixed target voltage V_Gtarget, when temperature is increased by driving of the power transistor 2, the period in which the gate voltage V_G rapidly changes in the early stage of driving may become relatively long and the period in which the gate voltage V_G gradually changes in the later stage of driving may become relatively short.

In this case, a gate driver having an effect that the turn-on operation is performed faster and overshoot is suppressed in comparison to using a fixed target voltage V_Gtarget can be provided.

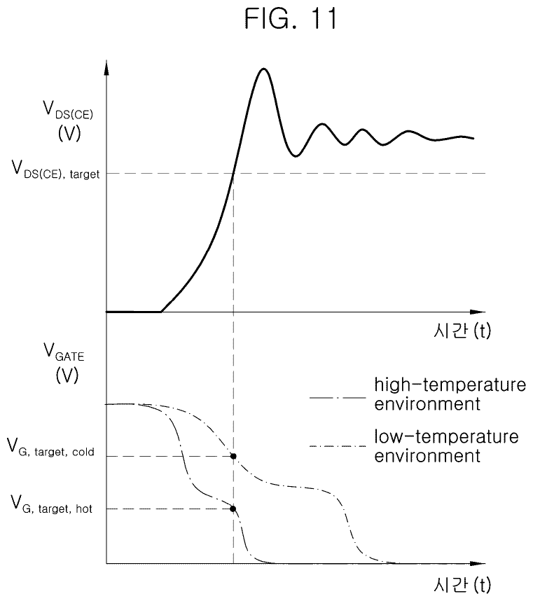

FIG. 11 is a graph showing a gate voltage corresponding to a drain-source voltage of a transistor according to an embodiment of the present disclosure.

Referring to FIG. 11, a drain-source voltage V_DS of the power transistor 2 in a turn-off process is shown in the upper graph in which the vertical axis is voltage over time that is the horizontal axis, and a gate voltage V_G of the power transistor 2 in a high-temperature environment and a low-temperature environment is shown in the lower graphs in which the vertical axis is voltage over time that is the horizontal axis.

When the turn-off switching step of the transistor 2 is divided based on the drain-source voltage V_DS of the transistor, the time point at which the turn-off switching step changes may be changed, depending on a high-temperature environment and a low-temperature environment.

In detail, in a high-temperature environment, the third switch 121 and the fourth switch 122 both can be turned on until the gate voltage V_G reaches V_Gtarget, hot, and the fourth switch 122 can be turned off after the gate voltage V_G reaches V_Gtarget, hot.

As compared with using a fixed target voltage V_Gtarget, the period in which the gate voltage V_G rapidly changes in the early stage of driving becomes relatively long and the period in which the gate voltage V_G gradually changes in the later stage of driving becomes relatively short, so a gate driver having an effect that the turn-off operation is performed faster and overshoot is suppressed in comparison to using a fixed target voltage V_Gtarget can be provided.

Accordingly, by designing a gate driver to change the target voltage in consideration of performance variation of a power transistor in a high-temperature environment, it is possible to provide a gate driver in which a switching operation can be performed faster and overshoot is reduced in comparison to using a fixed target voltage.

Meanwhile, the present disclosure can be achieved as computer-readable codes on a program-recoded medium. A computer-readable medium includes all kinds of recording devices that keep data that can be read by a computer system. For example, the computer-readable medium may be an HDD (Hard Disk Drive), an SSD (Solid State Disk), an SDD (Silicon Disk Drive), a ROM, a RAM, a CD-ROM, a magnetic tape, a floppy disk, and an optical data storage. Accordingly, the detailed description should not be construed as being limited in all respects and should be construed as an example. The scope of the present disclosure should be determined by reasonable analysis of the claims and all changes within an equivalent range of the present disclosure are included in the scope of the present disclosure.

What is claimed is:

1. A gate driver comprising:
an output line coupled with a gate of a transistor;
a high-side inverter comprising a first switch and a second switch each coupled at a first end with the output line and coupled at a second end with a first voltage source;
a low-side inverter comprising a third switch and a fourth switch each coupled at a first end with the output line and coupled at a second end with a second voltage source;
a sensor unit comprising a current sensor coupled with the transistor and configured to sense a collector-emitter current of the transistor; and
a control circuit coupled with the sensor unit and the first, second, third, and fourth switches and configured to turn on or turn off the transistor,
wherein in response to a turn-on signal being input, the control circuit turns on the first switch and selectively turns on the second switch based on a result of comparing the collector-emitter current and a preset target current.

2. The gate driver of claim 1, wherein the control circuit comprises:
a current source configured to output the preset target current; and
a first comparator coupled with the current source and the sensor unit and configured to output a signal in response that the sensed current is higher than a current output from the current source, wherein
the first switch is turned on in accordance with the turn-on signal, and
the second switch is selectively turned on based on the turn-on signal and output from the first comparator.

3. The gate driver of claim 2, wherein the control circuit comprises a first signal processing circuit coupled with the first comparator and the second switch and configured to turn on the second switch in response that the turn-on signal is input and a signal is not output from the first comparator.

4. The gate driver of claim 1, wherein the control circuit turns off both of the third switch and the fourth switch of the low-side inverter in response that the turn-on signal is input.

5. The gate driver of claim 1, wherein the sensor unit comprises a voltage sensor configured to sense a collector-emitter voltage of the transistor, and
in response that a turn-off signal is input, the control circuit turns on the third switch and selectively turns on the fourth switch based on a result of comparing the collector-emitter voltage and a preset target voltage.

6. The gate driver of claim 5, wherein the control circuit comprises:
a voltage source configured to output the preset target voltage; and
a second comparator coupled with the voltage source and the sensor unit and configured to output an on-signal in response that the sensed voltage is higher than or the same as a voltage output from the voltage source, wherein
the third switch is turned on in accordance with the turn-off signal, and
the fourth switch is selectively turned on based on the turn-off signal and output from the second comparator.

7. The gate driver of claim 6, wherein the control circuit comprises a second signal processing circuit coupled with the second comparator and the fourth switch and configured to turn on the fourth switch in response that the turn-off signal is input and a signal is not output from the second comparator.

8. The gate driver of claim 1, wherein the control circuit turns off both of the first switch and the second switch of the high-side inverter in response that the turn-off signal is input.

9. The gate driver of claim 1, wherein the first switch and the second switch each comprises a PMOS, sources of the first switch and the second switch are connected with the first voltage source, and drains of the first switch and the second switch are connected with the output line, and
the third switch and the fourth switch are each an NMOS, sources of the first switch and the second switch are connected with the second voltage source, and drains of the first switch and the second switch are connected with the output line.

10. The gate driver of claim 1, wherein the current sensor comprises a hall sensor coupled at a first end with an emitter of the transistor and coupled at a second end with the control circuit.

11. The gate driver of claim 5, wherein the voltage sensor comprises a voltage scaler coupled at a first end with a collector of the transistor, coupled at a second end with the control circuit, and configured to decrease a collector voltage of the transistor.

12. The gate driver of claim 5, further comprising:
a diode coupled at a first end with the control circuit, coupled at a second end with the voltage sensor, and configured such that current flows toward the voltage sensor; and
a current source coupled at a first end with the diode and the control circuit to prevent floating due to the diode.
